(19) United States
(12) Patent Application Publication
(10) Pub. No.: US 2026/0045460 A1
(43) Pub. Date: Feb. 12, 2026

(54) PLASMA PROCESSING APPARATUS AND PLASMA STATE DETECTION METHOD

(71) Applicant: Tokyo Electron Limited, Tokyo (JP)

(72) Inventors: Yudo SUGAWARA, Iwate (JP); Hideki YUASA, Yamanashi (JP)

(21) Appl. No.: 19/288,051

(22) Filed: Aug. 1, 2025

(30) Foreign Application Priority Data
Aug. 6, 2024 (JP) 2024-130101

(51) Int. Cl. H01J 37/32

(52) U.S. Cl. CPC H01J 37/32917; H01J 2237/24585

(57) ABSTRACT

A plasma processing apparatus includes: a processing container having an internal space; a substrate support unit provided within the internal space of the processing container; a gas supply unit that supplies a processing gas into the internal space of the processing container; a plasma generation unit that generates plasma within the internal space of the processing container; a vibration detection sensor provided outside the internal space of the processing container; and a control unit. The control unit is configured to detect a state of the plasma based on vibration detected by the vibration detection sensor.

### CROSS REFERENCES TO RELATED APPLICATIONS

This application is based on and claims priority from Japanese Patent Application No. 2024-130101, filed on Aug. 6, 2024, with the Japan Patent Office, the disclosure of which is incorporated herein in its entirety by reference.

### TECHNICAL FIELD

The present disclosure relates to a plasma processing apparatus and a plasma state detection method.

### BACKGROUND

Japanese Patent Laid-Open Publication No. 2006-128304 discloses a plasma processing apparatus including an accommodation chamber that accommodates a substrate, an electrode that is disposed in the accommodation chamber and applies radio-frequency power into the accommodation chamber, and a pipe that introduces a processing gas into the accommodation chamber. The plasma processing apparatus further includes a potential fluctuation detection unit that detects potential fluctuations, an ultrasonic detection unit that detects ultrasonic waves, and an abnormal discharge determination unit that determines that an abnormal discharge has occurred when both the potential fluctuations and the ultrasonic waves are detected.

Japanese Patent Laid-Open Publication No. 2011-014608 discloses an abnormality detection system that detects an abnormality occurring in a processing apparatus. The abnormality detection system includes a plurality of ultrasonic sensors that detect acoustic emissions generated in the processing apparatus, a distribution unit that divides respective output signals from the plurality of ultrasonic sensors into a first signal and a second signal, a trigger generation unit that samples the first signal at a first frequency and generates a trigger signal when a predetermined feature is detected, a trigger timing determination unit that receives the trigger signal and determine a trigger occurrence time, a data generation unit that samples the second signal at a second frequency higher than the first frequency to generate sampling data, and a data processing unit that analyzes the abnormality that has occurred in the processing apparatus by performing waveform analysis on the portion of the sampling data corresponding to a predetermined period based on the trigger occurrence time determined by the trigger timing determination unit.

### SUMMARY

According to an aspect of the present disclosure, a plasma processing apparatus includes: a processing container having an internal space; a substrate support unit provided within the internal space of the processing container; a gas supply unit that supplies a processing gas into the internal space of the processing container; a plasma generation unit that generates plasma within the internal space of the processing container; a vibration detection sensor provided outside the internal space of the processing container; and a control unit. The control unit is configured to detect a state of plasma based on vibration detected by the vibration detection sensor.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view illustrating a plasma processing apparatus according to an embodiment of the present disclosure.

FIG. 2 is a horizontal cross-sectional view illustrating the plasma processing apparatus according to an embodiment of the present disclosure.

FIG. 3 is a block diagram illustrating a functional configuration of a control unit.

FIG. 4 is a flowchart illustrating a plasma state detection method.

FIGS. 5A to 5D illustrate graphs representing examples of vibration detection results and analysis results.

### DETAILED DESCRIPTION

In the following detailed description, reference is made to the accompanying drawings, which form a part hereof. The illustrative embodiments described in the detailed description, drawings, and claims are not meant to be restricting. Other embodiments may be utilized, and other changes may be made without departing from the spirit or scope of the subject matter presented here.

Hereinafter, embodiments of the present disclosure will be described with reference to the accompanying drawings. In each of the drawings, the same components may be denoted by the same reference numerals, and redundant descriptions thereof may be omitted.

### Plasma Processing Apparatus

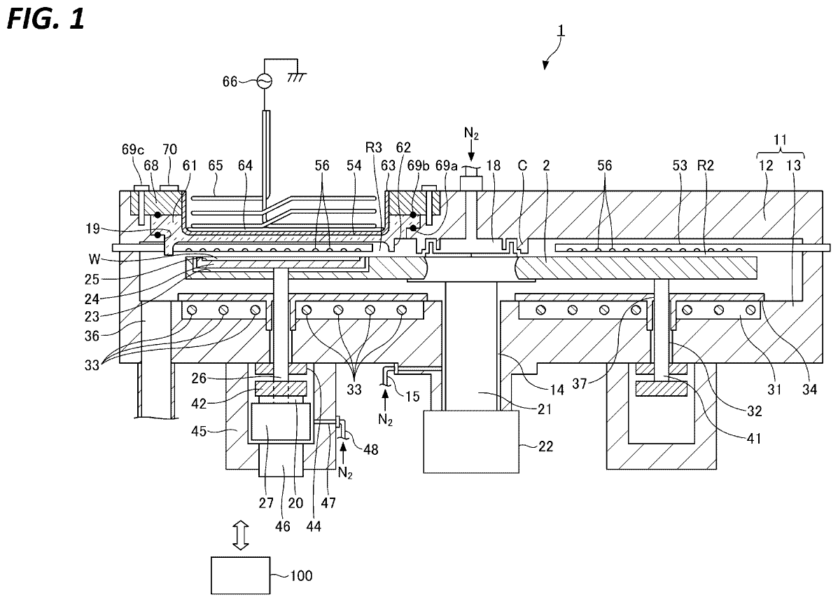

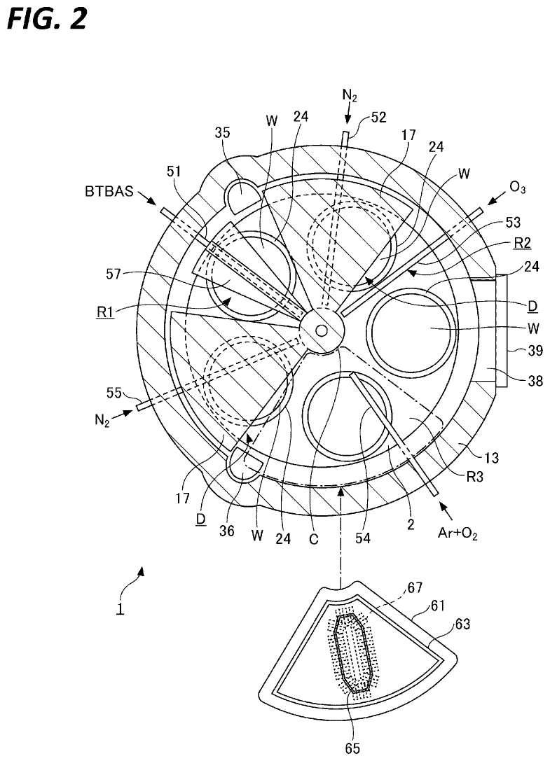

A plasma processing apparatus (film formation apparatus) 1 according to an embodiment of the present disclosure will be described with reference to FIGS. 1 and 2. FIG. 1 is a vertical cross-sectional view illustrating the plasma processing apparatus 1 according to an embodiment. FIG. 2 is a horizontal cross-sectional view illustrating the plasma processing apparatus 1 according to an embodiment. The plasma processing apparatus 1 is a substrate processing apparatus that performs a substrate processing (plasma processing) on a wafer W, which is an example of a substrate, by generating plasma inside a vacuum chamber 11.

In the following description, the plasma processing apparatus 1 will be described as an example a case where the apparatus serves as a film formation apparatus that forms a film on a wafer W by atomic layer deposition (ALD). The plasma processing apparatus (film formation apparatus) 1 forms a film on a wafer W by repeatedly performing the steps of: supplying a source gas to the wafer W to allow the source gas to be adsorbed onto the wafer W; supplying a reaction gas to the wafer W to react with the source gas adsorbed on the wafer W and form a molecular layer; and generating plasma of a modification gas and exposing the wafer W to the plasma to modify the molecular layer formed on the wafer W. In the following description, a case will be described in which bis(tert-butylamino)silane (BTBAS) gas, which is a processing gas containing silicon (Si), is used as the source gas; ozone (O₃) gas, which is an oxidizing gas (a processing gas containing oxygen (O)), is used as the reaction gas; and a mixed gas of argon (Ar) gas and oxygen (O₂) gas is used as the modification gas (plasma generation gas), to form a silicon oxide film (SiO₂) as the film formed on the wafer W.

The plasma processing apparatus 1 includes a substantially circular flat vacuum container 11 and a disk-shaped horizontal rotary table (substrate support unit) 2 installed inside the vacuum container 11. The vacuum container 11 includes a container ceiling plate 12 and a container body 13. The container body 13 has an open top and defines the side wall and bottom portion of the vacuum container 11. The container ceiling plate 12 covers an opening formed at the top of the container body 13 and defines the ceiling wall of the vacuum container 11.

At the center of the vacuum container 11, a central shaft 21 extends vertically downward from the center of the rotary table 2. The central shaft 21 is connected to a revolution rotary drive unit 22 provided to cover an opening 14 formed in the bottom portion of the container body 13. The rotary table 2 is supported inside the vacuum container 11 via the central shaft 21 and the revolution rotary drive unit 22. The rotary table 2 rotates clockwise or counterclockwise when viewed in a plan view of the plasma processing apparatus 1. The revolution rotary drive unit 22 is, for example, an electric actuator such as a motor. A gas supply pipe 15 injects nitrogen (N₂) gas into the gap between the central shaft 21 and the container body 13, thereby preventing or suppressing the source gas and the oxidizing gas from flowing around from the front surface to the rear surface of the rotary table 2.

On the lower surface of the container ceiling plate 12 of the vacuum container 11, a circular center region forming portion C that protrudes to face the central portion of the rotary table 2 when viewed in a plan view, and two convex portions 17 (see, e.g., FIG. 2) that extend outward from the center region forming portion C toward the outer side of the rotary table 2, are formed. The two convex portions 17 each have a substantially sector-shaped planar profile with a top portion cut into an arc shape.

The center region forming portion C and the convex portions 17 constitute a ceiling surface lower than that of the outer region. A gap between the center region forming portion C and the central portion of the rotary table 2 forms a flow path 18 for N₂ gas (see, e.g., FIG. 1). During processing of the wafer W, N₂ gas is supplied to the flow path 18 from a gas supply pipe connected to the container ceiling plate 12, and flows from the flow path 18 toward the entire outer periphery of the rotary table 2. The N₂ gas prevents or suppresses the source gas and the oxidizing gas from coming into contact with each other above the central portion of the rotary table 2.

At the bottom of the container body 13, a flat ring-shaped recess 31 is formed below the rotary table 2 to extend along the periphery of the rotary table 2. In the bottom surface of the recess 31, a ring-shaped slit 32 is formed to open along the circumferential direction of the recess 31, and the slit 32 penetrates through the bottom of the container body 13 in the thickness direction. On the bottom surface of the recess 31, seven ring-shaped heaters 33 are arranged to heat the wafer W placed on the rotary table 2.

The heaters 33 are arranged along concentric circles centered on the center of rotation of the rotary table 2. Among the seven heaters 33, four are provided inside the slit 32, and the remaining three are provided outside the slit 32. A shield 34 is provided to cover the upper side of each of the heaters 33 and to close the upper side of the recess 31. The shield 34 includes a ring-shaped slit 37 that overlaps the slit 32, and support columns 41 penetrate through both slits 32 and 37. In addition, exhaust ports 35 and 36 are formed in the bottom portion of the container body 13, outside the recess 31, for exhausting the interior of the vacuum container 11 (see, e.g., FIGS. 1 and 2). An exhaust mechanism (not illustrated) including, for example, a vacuum pump is connected to the exhaust ports 35 and 36.

As illustrated in FIG. 2, five circular recesses 23 are formed on the surface of the rotary table 2 along the rotational direction of the rotary table 2, and a circular wafer holder (substrate support unit) 24 is provided in each recess 23. As illustrated in FIG. 1, a recess 25 is formed in the surface of each wafer holder 24, and a wafer W is horizontally accommodated in the recess 25. Accordingly, the bottom surface of the recess 25 constitutes a mounting surface on which the wafer W is placed. In this example, the height of the side wall of the recess 25 is configured to be equal to the thickness of the wafer W, for example, 1 mm.

From positions spaced apart from each other in the circumferential direction on the rear surface of the rotary table 2, for example, three support columns 41 extend vertically downward. As illustrated in FIG. 1, each support column 41 penetrates the bottom portion of the container body 13 through the slits 32 and 37, and is connected to a support ring 42, which serves as a connecting portion provided below the container body 13. The support ring 42 is provided along the rotational direction of the rotary table 2 and is horizontally disposed to be suspended from the container body 13 by the support columns 41. The support ring 42 rotates together with the rotary table 2.

In addition, from the central lower portion of the wafer holder 24, a rotary shaft 26, which serves as a spin rotary shaft, extends vertically downward. The lower end of the rotary shaft 26 penetrates the rotary table 2, penetrates the bottom portion of the container body 13 through the slit 32, and further penetrates the support ring 42 and a magnetic seal unit 20 provided below the support ring 42, and is connected to a spin rotary drive unit 27. The magnetic seal unit 20 includes a bearing configured to rotatably support the rotary shaft 26 with respect to the support ring 42, and a magnetic seal (magnetic fluid seal) that seals a gap around the rotary shaft 26.

The magnetic seal is provided to suppress the diffusion of particles generated from the bearing, such as lubricant used in the bearing, into the vacuum atmosphere outside the magnetic seal unit 20. In addition, by being supported by the bearing, the rotary shaft 26 allows the wafer holder 24 to be in a slightly lifted state, for example, from the rotary table 2. The spin rotary drive unit 27 is provided below the support ring 42 to be supported by the support ring 42 via the magnetic seal unit 20, and rotates the rotary shaft 26 about the axis thereof. The spin rotary drive unit 27 is, for example, an electric actuator such as a motor. In the plasma processing apparatus 1, as the rotary table 2 rotates, the wafer W revolves, and in parallel with the rotation of the rotary table 2, the wafer holder 24 rotates so that the wafer W spins.

As illustrated in FIG. 1, the shield ring 44 is provided to close the slit 32 of the container body 13 from below the container body 13, and is configured to rotate together with the rotary table 2. Accordingly, the rotary shaft 26 and the support column 41 are provided to penetrate the shield ring 44. The shield ring 44 serves as a heat shield plate to prevent or supress the spin rotary drive unit 27 from being exposed to each processing gas or from being excessively heated.

Below the container body 13, a lower wall portion 45 is formed in a concave shape in cross-sectional view to surround the support ring 42, the spin rotary drive unit 27, and the shield ring 44. The lower wall portion 45 is formed in a ring shape along the rotational direction of the rotary table 2. In the bottom portion of the lower wall portion 45, five charging mechanisms 46 are provided at intervals in the circumferential direction (only one is illustrated in FIG. 1). When processing is not performed on the wafer W, the rotary table 2 remains stationary such that the spin rotary drive unit 27 is positioned directly below the charging mechanism 46, allowing each spin rotary drive unit 27 to be charged through non-contact power supply from a charging mechanism 46. A gas supply path 47 opens into the space surrounded by the lower wall portion 45. For example, during processing of the wafer W, a gas nozzle 48 supplies N₂ gas into the space surrounded by the lower wall portion 45 via the gas supply path 47 to purge the space. This space is, for example, in communication with an exhaust path that connects the exhaust ports 35 and 36 to an exhaust mechanism (not illustrated), and, even if particles are generated in the space, the particles are purged and removed by the N₂ gas.

A transfer port 38 for a wafer W and a gate valve 39 configured to open and close the transfer port 38 are provided in the side wall of the container body 13 (see, e.g., FIG. 2). A wafer W is transferred between a transfer apparatus that has entered the vacuum container 11 through the transfer port 38 and the recess 25. Specifically, through-holes are formed at corresponding positions in the bottom surface of the recess 25, the bottom portion of the container body 13, and the rotary table 2, respectively, and the tips of pins move up and down through the corresponding respective through-holes. The wafer W is transferred via these pins. Illustrations of these pins and the through-holes through which the pins penetrate each of the portions are omitted.

As illustrated in FIG. 2, on the rotary table 2, a source gas nozzle 51, a separation gas nozzle 52, an oxidizing gas nozzle 53, a plasma generation gas nozzle 54, and another separation gas nozzle 55 are arranged in this order at intervals along the rotational direction of the rotary table 2. Each of the gas nozzles 51 to 55 extends horizontally in a rod shape along the radial direction of the rotary table 2 from the side wall of the vacuum container 11 toward the center, and injects gas downward from multiple injection ports 56 formed along the radial direction. The respective gas nozzles (gas supply units) 51 to 55 are examples of gas supply units each configured to supply a gas into the vacuum container 11.

The source gas nozzle 51, which constitutes a processing gas supply mechanism, injects the bis(tert-butylamino)silane (BTBAS) gas. A nozzle cover 57 covers the source gas nozzle 51 and is formed in a sector shape that spreads both upstream and downstream in the rotational direction of the rotary table 2 from the source gas nozzle 51. The nozzle cover 57 serves to increase the concentration of the BTBAS gas below the nozzle cover, thereby enhancing the adsorption of the BTBAS gas onto the wafer W. The oxidizing gas nozzle 53 injects the above-described ozone (O₃) gas. The separation gas nozzles 52 and 55 are gas nozzles configured to inject N₂ gas, and are arranged to divide the sector-shaped convex portions 17 of the container ceiling plate 12 in the circumferential direction. The plasma generation gas nozzle 54 injects a plasma generation gas containing a mixed gas of, for example, argon (Ar) gas and oxygen (O₂) gas.

A sector-shaped opening 19 is provided in the container ceiling plate 12 along the rotational direction of the rotary table 2. A cup-shaped antenna ceiling plate (ceiling plate member) 61 made of a dielectric material such as quartz is provided to cover the opening 19 in a shape corresponding to the opening 19 (see, e.g., FIGS. 1 and 2). The antenna ceiling plate 61 is provided, when viewed in the rotational direction of the rotary table 2, between the oxidizing gas nozzle 53 and the convex portion 17. In FIG. 2, the position where the antenna ceiling plate 61 is provided is indicated by a one-dot chain line.

A protrusion 62 is provided along the peripheral edge on the lower surface of the antenna ceiling plate 61. A plasma generation region is formed between the antenna ceiling plate 61 and the rotary table 2 (wafer holder 24), within an area surrounded by the protrusion 62. The tip of the plasma generation gas nozzle 54 penetrates the protrusion 62 from the outer peripheral side of the rotary table 2 to inject gas into the plasma generation region surrounded by the protrusion 62. The protrusion 62 serves to suppress the entry of N₂ gas, ozone (O₃) gas, and BTBAS gas below the antenna ceiling plate 61, and to suppress a decrease in the concentration of the plasma generation gas.

A recess is formed above the antenna ceiling plate 61, and a box-shaped Faraday shield 63 that opens upward is disposed in the recess. On the bottom surface of the Faraday shield 63, an antenna 65 is provided via an insulating plate member 64. The antenna 65 has a configuration in which a metal wire is wound in a coil shape around a vertical axis. A radio-frequency power supply 66 is connected to the antenna 65. A slit 67 is formed in the bottom surface of the Faraday shield 63 so as to block the electric field component of the electromagnetic field generated in the antenna 65 during application of radio-frequency power to the antenna 65 from propagating downward, while allowing a magnetic field component to propagate downward (see, e.g., FIG. 2). A large number of slits 67, which extend in a direction orthogonal (intersecting) to the winding direction of the antenna 65, are formed along the winding direction of the antenna 65. With this configuration, the antenna 65 is coupled to the vacuum container 11 and configured to generate plasma within the vacuum container 11. When the radio-frequency power supply 66 is turned on and radio-frequency power is applied to the antenna 65, the plasma generation gas supplied below the antenna ceiling plate 61 may be turned into plasma. The antenna 65 and the radio-frequency power supply 66 constitute a plasma generation unit configured to generate plasma in the vacuum container 11.

The protrusion 62 of the antenna ceiling plate 61 and the region inside the protrusion 62 are inserted into the opening 19 of the container ceiling plate 12. The antenna ceiling plate 61 has a flange portion that extends outward in the horizontal direction beyond the protrusion 62. A lower peripheral edge of the flange portion is engaged with the container ceiling plate 12, and an upper peripheral edge of the flange portion is pressed and fixed by a pressing ring 68. That is, the flange portion of the antenna ceiling plate 61 is held by being sandwiched between the container ceiling plate 12 and the pressing ring 68. A sealing member 69a is disposed and sandwiched between the lower peripheral edge of the flange portion of the antenna ceiling plate 61 and the container ceiling plate 12. Another sealing member 69b is disposed and sandwiched between the upper peripheral edge of the flange portion of the antenna ceiling plate 61 and the pressing ring 68. The pressing ring 68 is fixed to the container ceiling plate 12 by a fastening member 69c such as a bolt.

The plasma processing apparatus 1 includes a vibration detection sensor 70 configured to detect radio-frequency vibrations of the plasma processing apparatus 1. As the vibration detection sensor 70, various types of vibration sensors, such as an acoustic emission (AE) sensor, a piezoelectric element, or a surface acoustic wave (SAW) sensor, may be widely used.

In particular, a vibration detection sensor that is capable of detecting vibrations in a wide frequency band (e.g., a frequency band of 0.01 Hz to 1,000 kHz) and employs a sheet-like piezoelectric element may be preferred as the vibration detection sensor 70. This allows for suitable detection of minute vibration phenomena in a predetermined radio-frequency band (e.g., a frequency band around 500 kHz, specifically a frequency band of 450 kHz to 550 kHz) with high sensitivity and a high signal-to-noise (S/N) ratio. Using the vibration detection sensor 70 capable of detecting vibrations in a wide frequency band may also allow detection of transient phenomena occurring at the time of plasma ignition.

According to an embodiment, the vibration detection sensor 70 may be provided on a member located close to the plasma generation region. Specifically, the vibration detection sensor 70 is provided on the pressing ring 68 that presses the antenna ceiling plate 61, which forms the ceiling of the plasma generation region. As a result, the vibration detection sensor 70 detects radio-frequency vibrations of the antenna ceiling plate 61. The vibration detection sensor 70 may be configured to be directly attached to the antenna ceiling plate 61.

The plasma processing apparatus 1 illustrated in FIGS. 1 and 2 has been described as having a single plasma generation region, but is not limited to this configuration. The plasma processing apparatus 1 may be configured to include a plurality of plasma generation regions. In such a case, each of the pressing rings 68, which press antenna ceiling plates 61 corresponding to respective plasma generation regions, may be provided with a vibration detection sensor 70.

On the rotary table 2, the region below the nozzle cover 57 of the source gas nozzle 51 is defined as an adsorption region R1 where BTBAS gas, as a source gas, is adsorbed. The region below the oxidizing gas nozzle 53 is defined as an oxidation region R2 where the BTBAS gas is oxidized by ozone (O₃) gas. The region below the antenna ceiling plate 61 is defined as a plasma formation region R3 where a SiO₂ film is modified by plasma. The region below the convex portion 17 serves to separate the adsorption region R1 and the oxidation region R2 from each other by nitrogen (N₂) gas injected from the separation gas nozzles 52 and 55, thereby forming separation regions D and D, respectively, so as to prevent or suppress mixing of the source gas and the oxidizing gas.

The exhaust port 35 is open to the outside between the adsorption region R1 and the separation region D adjacent to the adsorption region R1 on the downstream side in the rotation direction, and exhausts excess BTBAS gas. The exhaust port 36 is open to the outside near the boundary between the plasma formation region R3 and the separation region D adjacent to the plasma formation region R3 on the downstream side in the rotation direction, and exhausts excess O₃ gas and plasma generation gas. From the respective exhaust ports 35 and 36, nitrogen (N₂) gas supplied from each of the respective separation regions D, the gas supply pipe 15 below the rotary table 2, and the central region formation section C of the rotary table 2 is also exhausted.

The plasma processing apparatus 1 includes a control unit 100 configured to control the overall operation of the apparatus (see, e.g., FIG. 1). The control unit 100 is implemented using, for example, a computer. A program for executing a substrate processing method is stored in the control unit 100. The program controls the operations of respective components of the plasma processing apparatus 1 by transmitting control signals to the respective components. For example, gas flow rates supplied from the respective gas nozzles 51 to 55, the temperature of the wafer W heated by the heater 33, the flow rates of nitrogen (N₂) gas supplied from the gas supply pipe 15 and the central region formation section C, the rotation speed of the rotary table 2, and the rotation speed of the wafer holder 24 are controlled according to the control signals. In addition, process conditions for executing the substrate processing method are set step by step in a recipe (program). The recipe and other programs are installed in the control unit 100 from storage media such as a hard disk, compact disk, magneto-optical disk, memory card, or flexible disk.

In the plasma processing apparatus 1, as the rotary table 2 rotates, the wafer W revolves and repeatedly passes through the adsorption region R1, the separation region D, the oxidation region R2, the plasma formation region R3, and the other separation region D in this order, so that a film is formed by atomic layer deposition (ALD). While the rotary table 2 rotates as described above, the wafer W also spins by the rotation of the wafer holder 24. However, the rotation of the rotary table 2 and the rotation of the wafer holder 24 are not synchronized. The rotation of the rotary table 2 and rotation of the wafer holder 24 may, however, be synchronized. Specifically, when the rotary table 2 rotates once from a state in which the rotary table 2 is oriented in a first direction at a predetermined position within the vacuum chamber 11 and returns to the predetermined position, the wafer W may spin at a rotation speed (spinning speed) such that the wafer W is oriented in a second direction different from the first direction. For example, the rotation speed of the wafer W (unit: rpm) is set by the control unit 100 based on parameters that are specified by an operator via a specific setting screen, as will be described later.

### Plasma State Detection Method

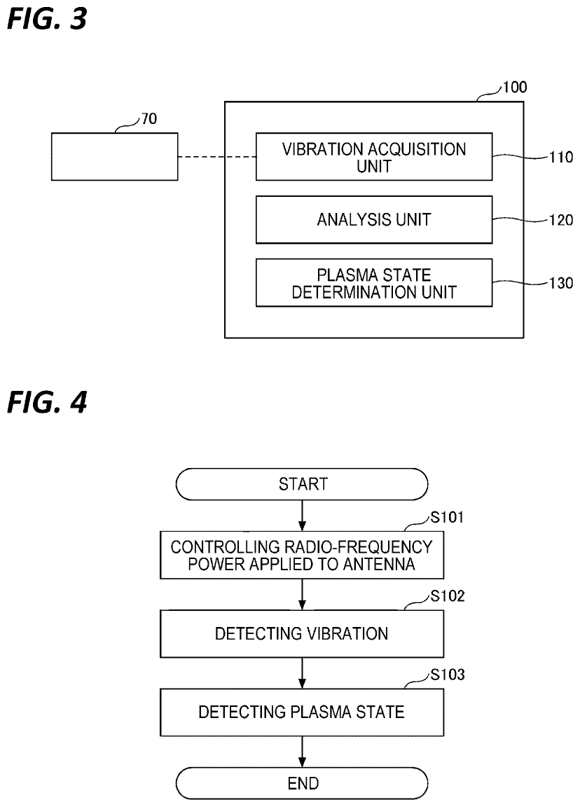

Next, a plasma state detection method will be described with reference to FIGS. 3 and 4. FIG. 3 is a block diagram illustrating a functional configuration of the control unit 100.

The control unit 100 includes a vibration acquisition unit 110, an analysis unit 120, and a plasma state determination unit 130.

The vibration acquisition unit 110 acquires a detection signal from the vibration detection sensor 70.

The analysis unit 120 analyzes the vibration acquired by the vibration acquisition unit 110. Here, the analysis unit 120 may perform frequency analysis of the vibration, for example, by performing Fourier analysis.

The plasma state determination unit 130 determines a plasma state based on the analysis result of the analysis unit 120. Specifically, based on the analysis result of the analysis unit 120, the plasma state determination unit 130 determines at least one of plasma ignition, ignition delay, and misfire.

FIG. 4 is a flowchart illustrating a plasma state detection method.

In step $101, radio-frequency power applied to the antenna 65 is controlled. Here, the control unit 100 controls the radio-frequency power supply 66 to adjust the radio-frequency power applied to the antenna 65. The control of the radio-frequency power applied to the antenna 65 includes, for example, initiation and termination of the application of the radio-frequency power to the antenna 65.

In step S102, vibrations of the pressing ring 68 (antenna ceiling plate 61) are detected. In this step, the vibration detection sensor 70 detects vibrations of the pressing ring 68 (antenna ceiling plate 61) and outputs a detection signal to the vibration acquisition unit 110. The vibration acquisition unit 110 then acquires the detection signal from the vibration detection sensor 70.

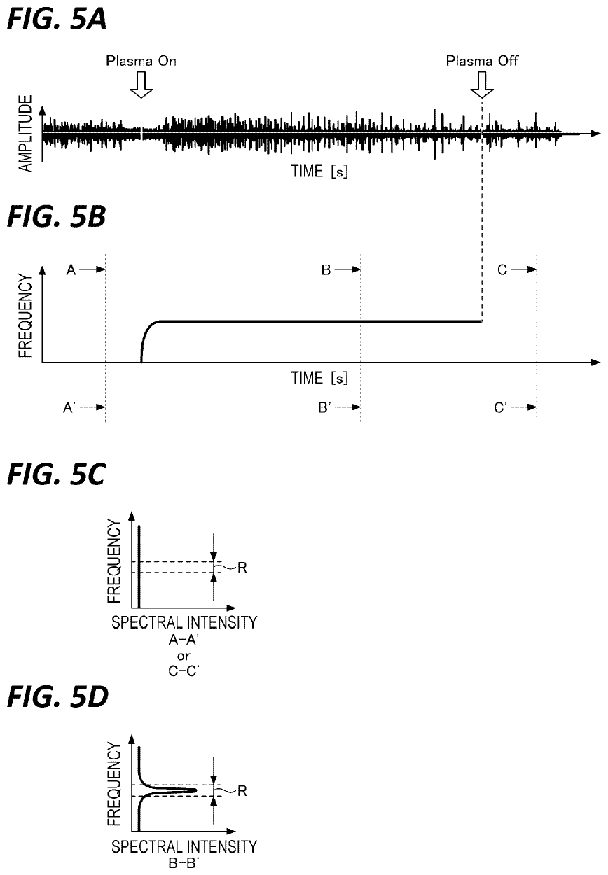

In step S103, a plasma state is detected. The control unit 100 determines the plasma state (at least one of plasma ignition, ignition delay, and misfire) based on the vibration of the pressing ring 68 (antenna ceiling plate 61) acquired by the vibration acquisition unit 110. Specifically, the analysis unit 120 performs frequency analysis, for example, by performing Fourier analysis on the vibration acquired by the vibration acquisition unit 110. Then, the plasma state determination unit 130 determines that plasma has been ignited when the spectral intensity in a predetermined radio-frequency band R (see, e.g., FIGS. 5C and 5D) (e.g., a frequency band around 500 kHz, specifically a frequency band of 450 kHz to 550 kHz) exceeds a predetermined threshold. In the Meantime, when the spectral intensity in the predetermined radio-frequency band R does not exceed the predetermined threshold, the plasma state determination unit 130 determines that a misfire of the plasma has occurred.

FIGS. 5A to 5D each illustrate graphs representing examples of vibration detection results and analysis results.

FIG. 5A illustrates the vibration (raw waveform) of the pressing ring 68 (antenna ceiling plate 61) detected by the vibration detection sensor 70 and acquired by the vibration acquisition unit 110. The horizontal axis represents time. The vertical axis represents the amplitude of the vibration. The timing of the initiation of radio-frequency power application to the antenna 65 (Plasma On) and the timing of the termination of radio-frequency power application to the antenna 65 (Plasma Off) are indicated by white arrows.

As illustrated in FIG. 5A, amplitudes of vibration appear before plasma generation (before Plasma On), during plasma generation (from Plasma On to Plasma Off), and after plasma generation (after Plasma Off).

FIG. 5B is a graph illustrating frequencies at which the spectral intensity of the vibration reaches a peak, obtained by performing frequency analysis on the vibration using Fourier analysis. The horizontal axis represents time. The vertical axis represents the vibration frequency at which the spectral intensity becomes maximal. Here, the analysis unit 120 performs frequency analysis on the vibration (see, e.g., FIG. 5A) by performing Fourier analysis and calculates the spectral intensity for each frequency. FIG. 5B illustrates a graph in which the vibration frequencies with peak (maximum) spectral intensity are plotted.

FIG. 5C is a graph representing the relationship between the vibration frequency and the spectral intensity at the time of plasma misfire (A-A′ or C-C′). FIG. 5D is a graph illustrating the relationship between the vibration frequency and the spectral intensity at the time of plasma ignition (B-B′). In FIGS. 5C and 5D, the vertical axes represent the vibration frequency, and the horizontal axis represents the spectral intensity corresponding to the vibration frequency.

As illustrated in FIGS. 5B and 5C, no spectral peak appears in the spectral intensity before plasma generation (before Plasma On).

As illustrated in FIG. 5B, when the application of radio-frequency power to the antenna 65 is initiated (Plasma On), the frequency at which the spectral intensity peaks changes transiently. That is, upon the initiation of radio-frequency power application to the antenna 65 (Plasma On), the frequency at which the spectral intensity peaks increases. Using the vibration detection sensor 70 capable of detecting a wide frequency range allows detection of such transient changes in vibration as illustrated in FIG. 5B. In other words, transient changes in the plasma state may also be detected.

As illustrated in FIGS. 5B and 5D, when the plasma has been ignited and the plasma state becomes stable, a spectral intensity peak appears in a predetermined radio-frequency band R. That is, the plasma state determination unit 130 may determine whether the plasma has been ignited based on whether a spectral intensity peak appears in the predetermined radio-frequency band R. In other words, the plasma state determination unit 130 may determine that the plasma has been ignited when the spectral intensity in the predetermined radio-frequency band R is equal to or greater than a predetermined threshold. In addition, when a time difference between the initiation of radio-frequency power application to the antenna 65 (Plasma On) and the time at which plasma ignition is determined exceeds a predetermined threshold time, the plasma state determination unit 130 may determine that ignition delay has occurred.

As illustrated in FIGS. 5B and 5C, when the application of radio-frequency power to the antenna 65 is terminated (Plasma Off), no peak appears in the spectral intensity. That is, the plasma state determination unit 130 may determine that a misfire of the plasma has occurred when the spectral intensity in the predetermined radio-frequency band R is less than a predetermined threshold.

As described above, the analysis unit 120 calculates the spectral intensity at each frequency from the amplitude of the detected vibration (see, e.g., FIG. 5A) by analyzing the vibration detected by the vibration detection sensor 70 (e.g., by performing Fourier analysis). Then, the plasma state determination unit 130 may detect a transient change in the plasma state based on the transient change in the frequency at which the spectral intensity peaks (see, e.g., FIG. 5B).

The plasma state determination unit 130 determines that the plasma has been ignited when the spectral intensity in the predetermined radio-frequency band R is equal to or greater than a predetermined threshold (see, e.g., FIG. 5D). In the meantime, the plasma state determination unit 130 determines that a misfire of the plasma has occurred when the spectral intensity in the predetermined radio-frequency band R is not equal to or greater than the predetermined threshold (see, e.g., FIG. 5C). Even in the case of an unexpected misfire of plasma, the misfire of the plasma may be detected by determining that the spectral intensity in the predetermined radio-frequency band R is not equal to or greater than the predetermined threshold.

The predetermined radio-frequency band R may be a frequency band including the natural frequency of vibration of the antenna ceiling plate 61 and/or the pressing ring 68, which vibrates due to plasma generation. The peak value and frequency bandwidth of the detected spectrum may vary depending on the natural frequency and stiffness of the object to which the sensor is attached.

There is known a plasma processing apparatus that detects the state of plasma by detecting plasma light emission within a vacuum container through a sapphire glass window provided in a side wall of a container body, using an optical detector disposed outside the container body. In comparison with such a plasma processing apparatus, the plasma processing apparatus 1 according to the present embodiment does not require an expensive sapphire glass window. As a result, the equipment cost may be reduced. Furthermore, since no window is required in the side wall of the container body, leakage may be suppressed.

By providing the vibration detection sensor 70 outside the processing space of the plasma processing apparatus 1 (e.g., on an upper surface of the pressing ring 68), the state of plasma may be detected.

The plasma processing apparatus 1, which detects the state of plasma based on the vibration detected by the vibration detection sensor 70, has been described using the configuration illustrated in FIGS. 1 and 2 as an example, but is not limited thereto. The configuration for detecting the state of plasma based on vibration detected by a vibration detection sensor may also be applied to an inductively coupled plasma (ICP) apparatus, a capacitively coupled plasma (CCP) apparatus, or a microwave plasma (MP) apparatus. In addition, although the plasma processing apparatus 1 has been described as an example of a film formation apparatus, the plasma processing apparatus is not limited thereto and may be applied to a plasma etching apparatus.

According to an aspect, it may be possible to provide a plasma processing apparatus and a reaction tube wall protection member that suppress consumption of a reaction tube.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A plasma processing apparatus comprising:
a processing container having an internal space;
a substrate support provided within the internal space of the processing container;
a gas supply configured to supply a processing gas into the internal space of the processing container;
a plasma generator configured to generate plasma within the internal space of the processing container;
a vibration detection sensor provided outside the internal space of the processing container; and
a controller,
wherein the controller is configured to detect a state of the plasma based on vibration detected by the vibration detection sensor.

2. The plasma processing apparatus of claim 1, wherein the controller is further configured to:
analyze the vibration detected by the vibration detection sensor to calculate a spectral intensity corresponding to a frequency; and
detect the state of the plasma based on a transient change in a peak of the spectral intensity.

3. The plasma processing apparatus of claim 1, wherein the controller is further configured to:
analyze the vibration detected by the vibration detection sensor to calculate a spectral intensity corresponding to a frequency; and
detect at least one of ignition, ignition delay, and misfire of the plasma based on the spectral intensity in a predetermined frequency band.

4. The plasma processing apparatus of claim 3, wherein the processing container includes:
a container body having an open top;
a container ceiling plate configured to close the open top;
an antenna ceiling plate disposed in an opening of the container ceiling plate and positioned above a plasma generation region; and
a pressing ring configured to fix the antenna ceiling plate to the container ceiling plate, and
wherein the vibration detection sensor is provided on the antenna ceiling plate or the pressing ring.

5. The plasma processing apparatus of claim 4, wherein the predetermined frequency band includes a natural frequency of the antenna ceiling plate or the pressing ring.

6. A plasma state detection method comprising:
providing a plasma processing apparatus including a processing container having an internal space, a substrate support provided within the internal space of the processing container, a gas supply configured to supply a processing gas into the internal space of the processing container, a plasma generator configured to generate plasma within the internal space of the processing container, and a vibration detection sensor provided outside the internal space of the processing container; and
detecting a state of plasma based on vibration detected by the vibration detection sensor.

7. The method of claim 6, further comprising:
analyzing the vibration detected by the vibration detection sensor to calculate a spectral intensity corresponding to a frequency; and
detecting a state of the plasma based on a transient change in a peak of the spectral intensity.

8. The method of claim 6, further comprising:
analyzing the vibration detected by the vibration detection sensor to calculate a spectral intensity corresponding to a frequency; and
detecting ignition or misfire of the plasma based on the spectral intensity in a predetermined frequency band.
